(19) United States
(12) Patent Application Publication
(10) Pub. No.: US 2010/0230623 A1
(43) Pub. Date: Sep. 16, 2010

(54) PIEZOELECTRIC ACTUATOR

(76) Inventor: Friedrich Boecking, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/303,894

(22) PCT Filed: May 22, 2007
(86) PCT No.: PCT/EP2007/054918

§ 371 Date: Dec. 8, 2008

(30) Foreign Application Priority Data
Jun. 8, 2006 (DE) 10 2006 026 644.7

(51) Int. Cl. F16K 31/02; H01L 41/047; H01L 41/083

(52) U.S. Cl. 251/129.06; 310/366

(57) ABSTRACT

A piezoelectric actuator for a fuel injection valve has an actuator body with a plurality of ceramic layers and a plurality of electrode layers between the ceramic layers. There is a connection area between an electrode layer and a ceramic layer adjacent to the electrode layer, where the adhesive strength between the electrode layer and the ceramic layer is reduced in parts of the connection area to provide for a predetermined breaking point within the actuator body. This allows for a controlled rupture of layers within the actuator body with high forces, in particular high shear forces such as those that occur with stress due to shock.

### PRIOR ART

The invention relates to a piezoelectric actuator for a fuel injection valve and to a fuel injection valve having such a piezoelectric actuator. The invention relates in particular to the field of injectors for fuel injection systems of air-compressing, self-igniting internal combustion engines.

From German Patent Disclosure DE 102 06 115 A1, a piezoceramic many-layered actuator is known. The known actuator comprises stacked thin layers of piezoelectricity active material, with conductive inner electrodes located between them that extend in alternation to the surface of the actuator. Outer electrodes connect the inner electrodes, and as a result the inner electrodes are connected electrically parallel and are combined into two groups. The two outer electrodes represent the terminal poles of the actuator. The outer electrode has a base metallization, which connects the inner electrodes of identical polarity. A further layer comprising a metal material is also provided, which reinforces the base metallization and which can be formed for instance by a structured metal sheet or a wire mesh. In operation of the known actuator, the problem is that severe tensile stresses act on the inactive region, that is, the insulating region, which is located beneath the base metallization. As a result, cracks can occur, which extend from the brittle base metallization that has low tensile strength into the insulating region.

In DE 102 06 115 A1, the propagation of a crack along an inner electrode that touches the base metallization is classified as not critical, since this kind of course of a crack would not impair the function of the actuator. Conversely, cracks that extend uncontrolled through the insulating region are classified as critical, since they reduce the insulation spacing and greatly increase the likelihood of actuator failure from sparkovers. In the actuator known from DE 102 06 115 A1, a structure is created on the surface of the inactive region, that is, the insulating region, by eroded places that interrupt the surface area and extend over a multiplicity of layers. The base metallization for the outer electrodes is applied solely to the surface that remains as a result of the structure, so that the outer electrode is not bonded over its full surface to the surface of the many-layered actuator, and the rigidity of the combination is lessened.

The actuator known from DE 102 06 115 A1 has the disadvantage that in impact stress or on the occurrence of shear forces inside the actuator, considerable stresses can still occur. Moreover, in the known actuator, between an electrode layer and a ceramic layer adjacent to the electrode layer, a stress can occur that leads to cracking of the ceramic or to cracking along the inner electrode. In particular, a cracked inner electrode can tear all the way through, so that the function of the actuator is destroyed in the region of the cracked inner electrode.

### DISCLOSURE OF THE INVENTION

### Advantages of the Invention

The piezoelectric actuator of the invention having the characteristics of claim 1 and the fuel injection valve of the invention having the characteristics of claim 11 have the advantage over the prior art that, preferably at a plurality of different places in the actuator, layers are provided in which the adhesive strength is intentionally reduced. As a result, especially upon impact stress or on the occurrence of shear forces, uncontrolled cracking of the ceramic in the actuator and/or uncontrolled cracking of an inner electrode can be prevented. In particular, the reliability of the piezoelectric actuator of the invention and of the fuel injection valve of the invention can be improved.

By the provisions recited in the dependent claims, advantageous refinements of the piezoelectric actuator defined by claim 1 and of the fuel injection valve defined by claim 1 are possible.

It is advantageous that the connection region has at least one partial region, in which the adhesive strength between the electrode layer and the ceramic layer is reduced. As a result, the creation and propagation of stresses between the layers in the partial region having the reduced adhesive strength is reduced or prevented. Uncontrolled cracking of the layers is thus prevented.

It is moreover advantageous that in the partial region of the connection region in which the adhesive strength between the electrode layer and the ceramic layer is reduced, the electrode layer is embodied as roughened. In the roughening, particularly by means of the parameters of peak-to-valley height and patterning, electrode layers can be produced in a targeted and simple way without having to modify the composition of the paste, used to produce the electrode layer, with respect to the partial region in particular, the production of the electrode layer with a paste of a defined composition is possible.

Advantageously, the partial region of the connection region in which the adhesive strength between the electrode layer and the ceramic layer is reduced is designed as a function of the geometry and the inner electrode construction of the actuator body. In particular, the contour of the partial region is advantageously selected as a function of the geometry and of the inner electrode construction. It is advantageous that in the case of a cylindrical actuator body, the partial region is embodied as a circular-annular partial region. Moreover, in the case of a block-shaped actuator body, the embodiment of the partial region in which the adhesive strength is reduced as a rectangular partial region is advantageous. As a result, high reliability with respect to the function of the electrode layer can be assured even if the electrode layer partially cracks.

It is furthermore advantageous that the connection region has at least one adhesive partial region, in which the adhesive strength between the electrode layer and the ceramic layer is greater than the adhesive strength in the partial region in which the adhesive strength between the electrode layer and the ceramic layer is reduced. By means of the adhesive partial region, a rated breaking point with respect to the electrode layer and/or the ceramic layer can be created, so that in the event of correspondingly major stresses, controlled cracking of the electrode layer and/or of the ceramic layer occurs at certain predetermined points.

Advantageously, a further connection region between the electrode layer and a further ceramic layer adjacent to the electrode layer is provided, in which the adhesive strength between the electrode layer and the further ceramic layer is partially reduced. As a result, a partial reduction in the adhesive strength to the ceramic layer or to the further ceramic layer is made possible on both sides of the electrode layer. The regions of reduced adhesive strength are preferably disposed on both sides of the electrode layer in a way that is adapted to one another, so that rated breaking points can be predetermined intentionally, thus preventing uncontrolled cracking of the electrode layer.

### DRAWINGS

Preferred exemplary embodiments of the invention are described in further detail in the ensuing description in conjunction with the accompanying drawings, in which corresponding elements are identified by the same reference numerals.

FIG. 1 shows a fuel injection valve with a piezoelectric actuator, in a schematic sectional view, in a first exemplary embodiment of the invention;

FIG. 2 shows the detail, marked I in FIG. 1, of a piezoelectric actuator of the invention in a detailed sectional view along the section line marked II in FIG. 3;

FIG. 3 shows a section through the piezoelectric actuator of the first exemplary embodiment of the invention along the section line marked III in FIGS. 1 and 2; and

FIG. 4 shows the section, shown in FIG. 3, through a piezoelectric actuator in a second exemplary embodiment of the invention.

### DESCRIPTION OF THE EXEMPLARY EMBODIMENTS

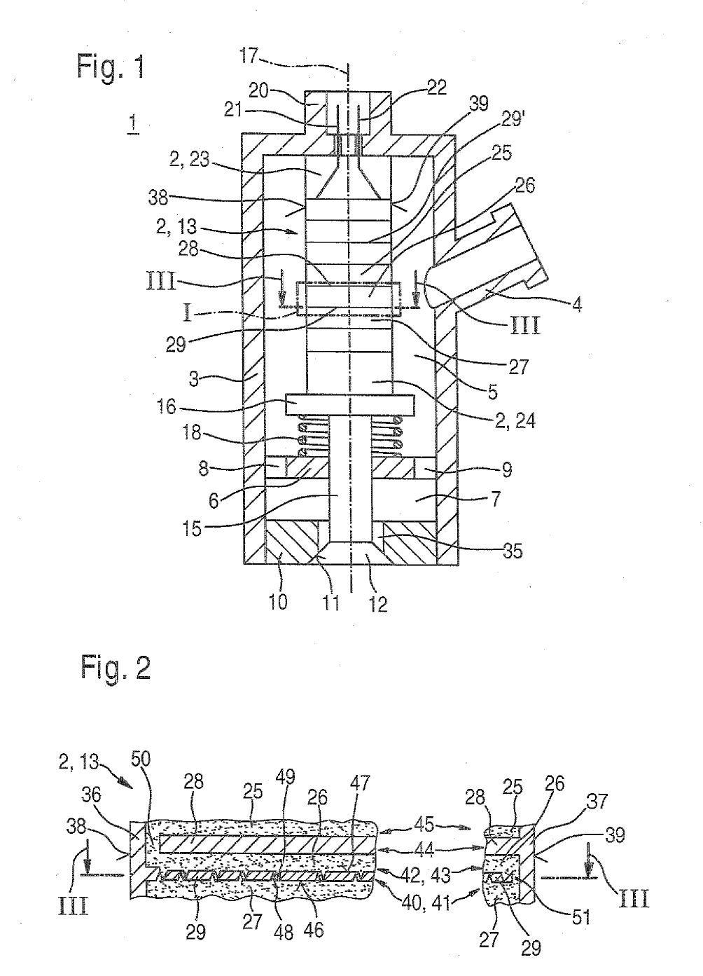

FIG. 1 shows a fuel injection valve 1 with a piezoelectric actuator 2, in a first exemplary embodiment of the invention. The fuel injection valve 1 can serve in particular as an injector for fuel injection systems of mixture-compressing, self-igniting internal combustion engines. A preferred use of the fuel injection valve 1 is for a fuel injection system with a common rail that carries diesel fuel at high pressure to a plurality of fuel injection valves 1. The piezoelectric actuator 2 of the invention is especially well suited to this kind of fuel injection valve 1. However, the fuel injection valve 1 of the invention and the actuator 2 of the invention are suitable for other applications as well.

The fuel injection valve 1 has a valve housing 3 and a fuel inlet stub 4 communicating with the valve housing 3. A fuel line can be connected to the fuel inlet stub 4 in order to introduce fuel into an actuator chamber 5 provided in the interior of the valve housing 3. The actuator chamber 5 is separated by a housing part 6 from a fuel chamber 7 also provided in the interior of the valve housing 3. In the housing part 6, through openings 8, 9 are provided, in order to direct the fuel, carried into the actuator chamber 5 via the fuel inlet stub 4, into the fuel chamber 7.

A valve seat face 11, which cooperates with a valve closing body 12 to form a sealing seat, is embodied on a valve seat body 10 that is connected to the valve housing 3. The valve closing body 12 is embodied integrally with a valve needle 15, by way of which the valve closing body 12 is connected to a pressure plate 16 provided in the actuator chamber 5. The housing part 6 guides the valve needle 15 in the direction of an axis 17 of the fuel injection valve 1. A valve spring 18, which on one end contacts the housing part 6 and on the other contacts the pressure plate 16, subjects the valve needle 15, by means of the pressure plate 16, to a closing force, so that the sealing seat formed between the valve closing body 12 and the valve seat face 11 is closed.

Also on the valve housing 3, a connection element 20 is embodied, in order to connect an electric supply line to the fuel injection valve 1. The electric supply line can be connected by means of a plug to electric lines 21, 22. The electric lines 21, 22 are extended through the housing 3 and through an actuator foot 23, joined to an actuator body 13 of the actuator 2. An actuator head 24 is also joined to the actuator body 13 of the actuator 2, and by way of it, the actuator body 13 acts on the pressure plate 16 counter to the force of the valve spring 18. In the exemplary embodiment shown, the actuator 2 includes the actuator body 13, the actuator foot 23, and the actuator head 24.

The actuator body 13 of the piezoelectric actuator 2 has a multiplicity of ceramic layers 25, 26, 27 and a multiplicity of electrode layers 28, 29 disposed between the ceramic layers 25, 26, 27. In FIG. 1, only the ceramic layers 25, 26, 27 and the electrode layers 28, 29, 29′ are identified by reference numerals for the sake of representation. The electrode layers 28, 29, 29′ are connected in alternation to the electric line 21 and to the electric line 22. For example, the electrode layers represented by the electrode layer 28 are connected to the electric line 21, and these form the positive electrodes; and the electrode layers represented by the electrode layer 29 are connected to the electric line 22, and they form the negative electrodes.

By way of the electric lines 21, 22, the actuator 2 can be charged; in the process, it expands in the direction of the axis, so that the sealing seat embodied between the valve closing body 12 and the valve seat face 11 is opened. The result is the ejection of fuel from the fuel chamber 7 via an annular gap 35 and the opened sealing seat. On discharging of the actuator 2, the actuator contracts again, so that the sealing seat formed between the valve closing body 12 and the valve seat face 11 is closed.

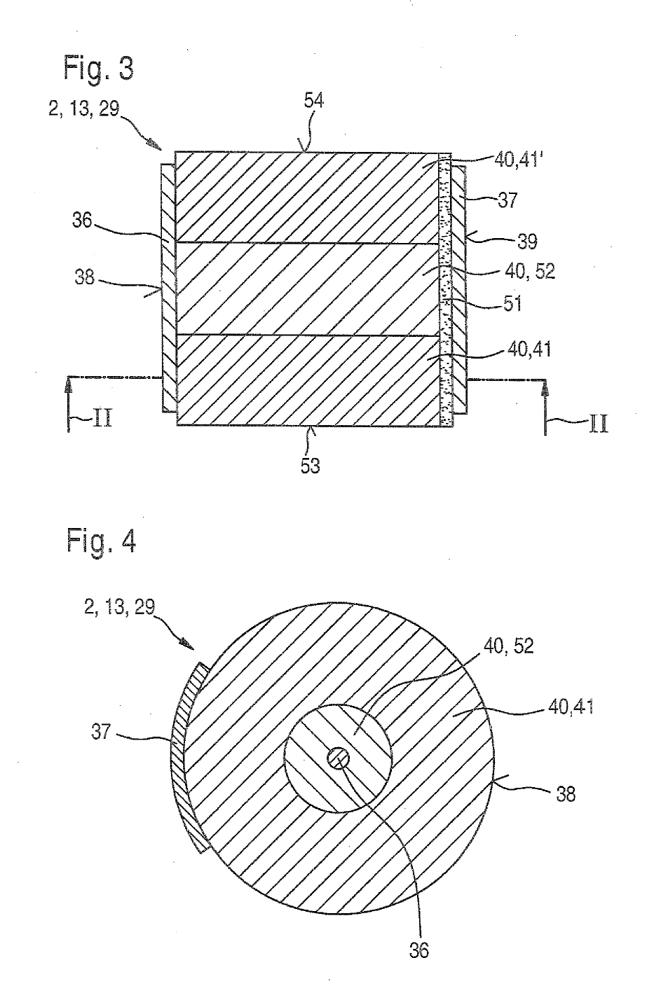

The connection of the electric lines 21, 22 to the electrode layers 28, 29 can be effected by means of external electrode connections 36, 37 (FIG. 2), which are provided on an outer side 38 or outer side 39 of the actuator 2, or by means of internal electrode connections. Each two adjacent layers of the actuator body 13, namely one of the electrode layers 28, 29 and one of the ceramic layers 25, 26, 27, are mechanically connected to one another, in order to assure a mechanical stability of the actuator body 13. The embodiment of the actuator body 13 of the actuator 2 will be described below in detail in conjunction with FIGS. 2 and 3.

FIG. 2 shows the detail marked I in FIG. 1 in a fragmentary sectional view along the section line II in FIG. 3.

With respect to the electrode layer 29, a connection region 40 is provided between the electrode layer 29 and the ceramic layer 27 adjacent to the electrode layer 29; FIG. 2 shows a section through a partial region 41 of the connection region 40, in which partial region the adhesive strength between the electrode layer 29 and the ceramic layer 27 is reduced. With respect to the electrode layer 29, a further connection region 42 between the electrode layer 29 and the ceramic layer 26 adjacent to the electrode layer 29, which ceramic layer is diametrically opposite the ceramic layer 27 relative to the electrode layer 29, is provided; FIG. 2 shows a section through a partial region 43 of the further connection region 42, in which the adhesive strength between the electrode layer 29 and the ceramic layer 26 is reduced. Moreover, between the electrode layer 28 and the ceramic layer 26 adjacent to the electrode layer 28, a connection region 44 of normal adhesive strength, or in other words with an unreduced adhesive strength, is provided, and between the electrode layer 28 and the ceramic layer 25, which is adjacent to the electrode layer 28 and is diametrically opposite the ceramic layer 26 relative to the electrode layer 28, a connection region 45 with normal adhesive strength is embodied.

The electrode layer 29 has a surface 46 and a surface 47, the latter facing away from the surface 46. The surface 46 is roughened and patterned in the partial region 41 of the connection region 40. Moreover, the surface 47 in the partial region 43 of the further connection region 42 is also roughened and patterned. This embodiment of the electrode layer 29 is effected preferably in the crude state of the electrode layer 29, or in other words especially before the sintering of the actuator body 13 in which the layers 25 through 29 cure. The result, in the cured actuator body, is the reduced adhesive strength in both the partial region 41 of the connection region 40 and the partial region 43 of the further connection region 42. The patterning of the surfaces 46, 47, which can be embodied for instance by a plurality of grooves 48, 49 in the surface 46 and the surface 47, respectively, rating breaking points are also produced inside the partial regions 41, 43, and as a result, in the event of suitably strong forces acting on the electrode layer 28, in particular shear forces, a controlled cracking of the electrode layer 29 is made possible. The rated breaking points, that is, the partial regions 41, 43 of reduced adhesive strength, are distributed over the connection regions 40, 42 in such a way that the function of the electrode layer 29 is at least largely preserved even after controlled cracking. In the region of the outer side 38, a strut 50 of ceramic material is provided, which connects the ceramic layers 25, 26 and at the same time insulates the electrode layer 28 from the electrode connection 36. A strut 51 of ceramic material is also provided that connects the ceramic layers 26, 27 to one another and at the same time insulates the electrode layer 29 from the electrode connection 37.

FIG. 3 shows a section through the piezoelectric actuator 2 of the fuel injection valve 1 of the first exemplary embodiment of the invention, along the section line marked III in FIGS. 1 and 2. The connection region 40 has the partial region 41 of reduced adhesive strength and has a further partial region 41′, corresponding to the partial region 41, and the adhesive strength between the electrode layer 29 and the ceramic layer 26 adjacent to the electrode layer 29 is reduced in the further partial region 41′ in a corresponding way. The connection region 40 furthermore has an adhesive partial region 52, in which the adhesive strength between the electrode layer 29 and the ceramic layer 26 adjacent to the electrode layer 29 is not reduced and is thus greater than the adhesive strength in the partial regions 41, 41′. The embodiment of the electrode layer 29 and of the ceramic layer 26, adjacent to the electrode layer 29, in the adhesive partial region 52 of the connection region 40 is equivalent to the embodiment as shown in FIG. 2 in terms of the electrode layer 28 and the ceramic layer 25 adjacent to the electrode layer 28. The electrode layer 29 in the adhesive partial region 52 of the connection region 40 has no or only relatively slight roughness and no or only slight patterning in its surface 46. The surface 47 of the electrode layer 29, in an adhesive partial region diametrically opposite the adhesive partial region 52, of the further connection region 42 is also designed as at least substantially plane, or in other words with no or only slight roughness and no or only slight patterning.

Upon the occurrence of relatively major stresses in the layers 25 through 29 of the actuator body 13, controlled cracking of the electrode layer 29 and/or of the ceramic layer 27 adjacent to the electrode layer 29 can occur in the partial region 41 and/or the partial region 41′ of the connection region 40; cracking of the electrode layer 29 and/or of the ceramic layer 27 in the adhesive partial region 52 of the connection region 40 is at least substantially prevented. Moreover, in the partial regions 41, 41′ of the connection region 40, a certain shifting between the electrode layer 29 and the ceramic layer 27 is made possible. Since cracking of the electrode layer 29 and/or of the ceramic layer 26 in the adhesive partial region 52 of the connection region 40 is at least substantially prevented, the function with respect to the layers 29, 27 is preserved. Stresses occurring in the region of the layers 25, 28, 26 as well are absorbed via the layered construction between the electrode layer 29 and the adjacent ceramic layers 26, 27, so that the function with respect to the electrode layer 28 and the ceramic layers 25, 26 adjacent to the electrode layer 28 is also preserved. Preferably, a certain number among the multiplicity of electrode layers 28, 29 of the actuator body 13 are designed like the electrode layer 29, and the electrode layers designed like the electrode layer 29 are preferably distributed uniformly over the actuator body 13, so that high reliability of the entire actuator body 13 of the piezoelectric actuator 2 is assured. For example, every n^{th} electrode layer of the actuator body 13 can be designed like the electrode layer 29, where n is an integer greater than or equal to 1. For instance, if n is equal to 3, then the electrode layer 29′ of the actuator body 13 can also be designed like the electrode layer 29, as shown in FIG. 1.

In the first exemplary embodiment of the invention shown in FIGS. 1 through 3, the actuator body 13 of the piezoelectric actuator 2 is embodied as a block-shaped actuator body 13. Accordingly, the section shown in FIG. 3 shows a rectangular, in particular square, sectional face through the actuator body 13. The connection region 40 has rectangular partial regions 41, 41′ and a rectangular adhesive partial region 52 located between the partial regions 41, 41′. The adhesive partial region 52 extends from the electrode connection 36 in the region of the outer side 38 to the strut 51 at the electrode connection 37 in the region of the outer side 39. The partial region 41 extends from the electrode connection 36 to the strut 51 at the electrode connection 37 and is adjacent on one side to an outer side 53 of the actuator body 13 and on the other to the adhesive partial region 52. The partial region 41′ furthermore extends from the electrode connection 36 to the strut 51 at the electrode connection 37 and is adjacent on one side to an outer side 54 and on the other to the adhesive partial region 52. An alternative embodiment is described below in conjunction with FIG. 4.

FIG. 4 shows the section, shown in FIG. 3, through the actuator body 13 in a second exemplary embodiment of the invention. In this exemplary embodiment, the actuator body 13 is embodied cylindrically, and thus the actuator body 13 has the circular cross section shown in FIG. 4. In this case, the partial region 41 of the connection region 40 is embodied as a circular-annular partial region 41, and the partial region 41 extends as far as an outer side 38 of the actuator body 13. The adhesive partial region 52 located in the interior of the circular-annular partial region 41 is embodied as a circular adhesive partial region 52. The connection of electrodes 36, 37 to the actuator body 13 shown in FIG. 4 can be done in various ways. For instance, an internal electrode connection 36 extending centrally through the actuator body 13 may be provided, as shown in FIG. 4, which is connected to the electrode layers, represented by the electrode layer 29, of the actuator body 13. The electrode connection 37 can be provided as an external electrode connection 37, for instance, that is suitably connected to the electrode layers represented by the electrode layer 28 and is insulated from the electrode layers represented by the electrode layer 29.

The invention is not limited to the exemplary embodiments described.

1-11. (canceled)

12. A piezoelectric actuator, in particular an actuator for fuel injection valves, comprising:
an actuator body having a multiplicity of ceramic layers and a multiplicity of electrode layers disposed between the ceramic layers; and
at least one connection region provided between one electrode layer and one ceramic layer adjacent to the electrode layer, wherein the adhesive strength between the electrode layer and the ceramic layer is partially reduced in the at least one connection region.

13. The piezoelectric actuator as defined by claim 12, wherein the connection region has at least one partial region, in which the adhesive strength between the electrode layer and the ceramic layer is reduced.

14. The piezoelectric actuator as defined by claim 13, wherein in the partial region of the connection region in which the adhesive strength between the electrode layer and the ceramic layer is reduced, the electrode layer is embodied as roughened.

15. The piezoelectric actuator as defined by claim 13, wherein in the partial region of the connection region in which the adhesive strength between the electrode layer and the ceramic layer is reduced, the electrode layer has a roughened and/or patterned surface.

16. The piezoelectric actuator as defined by claim 14, wherein in the partial region of the connection region in which the adhesive strength between the electrode layer and the ceramic layer is reduced, the electrode layer has a roughened and/or patterned surface.

17. The piezoelectric actuator as defined by claim 13, wherein the actuator body is embodied substantially as a cylindrical actuator body; and the partial region is embodied as an at least approximately circular-annular partial region.

18. The piezoelectric actuator as defined by claim 14, wherein the actuator body is embodied substantially as a cylindrical actuator body; and the partial region is embodied as an at least approximately circular-annular partial region.

19. The piezoelectric actuator as defined by claim 15, wherein the actuator body is embodied substantially as a cylindrical actuator body; and the partial region is embodied as an at least approximately circular-annular partial region.

20. The piezoelectric actuator as defined by claim 13, wherein the actuator body is embodied substantially as a block-shaped actuator body; and the partial region is embodied as an at least approximately rectangular partial region.

21. The piezoelectric actuator as defined by claim 14, wherein the actuator body is embodied substantially as a block-shaped actuator body; and the partial region is embodied as an at least approximately rectangular partial region.

22. The piezoelectric actuator as defined by claim 15, wherein the actuator body is embodied substantially as a block-shaped actuator body; and the partial region is embodied as an at least approximately rectangular partial region.

23. The piezoelectric actuator as defined by claim 13, wherein the connection region has at least one adhesive partial region, in which an adhesive strength between the electrode layer and the ceramic layer is greater than the adhesive strength in the partial region in which the adhesive strength between the electrode layer and the ceramic layer is reduced.

24. The piezoelectric actuator as defined by claim 14, wherein the connection region has at least one adhesive partial region, in which an adhesive strength between the electrode layer and the ceramic layer is greater than the adhesive strength in the partial region in which the adhesive strength between the electrode layer and the ceramic layer is reduced.

25. The piezoelectric actuator as defined by claim 11, wherein a further connection region between the electrode layer and a further ceramic layer adjacent to the electrode layer is provided, in which the adhesive strength between the electrode layer and the further ceramic layer is partially reduced.

26. The piezoelectric actuator as defined by claim 13, wherein a further connection region between the electrode layer and a further ceramic layer adjacent to the electrode layer is provided, in which the adhesive strength between the electrode layer and the further ceramic layer is partially reduced.

27. The piezoelectric actuator as defined by claim 13, wherein a plurality of connection regions between the electrode layers and the ceramic layers between adjacent to electrode layers and ceramic layers are provided, in which the adhesive strength between the respective electrode layer and the respective ceramic layer adjacent to the electrode layer is partially reduced.

28. The piezoelectric actuator as defined by claim 13, wherein a plurality of connection regions between the electrode layers and the ceramic layers between adjacent to electrode layers and ceramic layers are provided, in which the adhesive strength between the respective electrode layer and the respective ceramic layer adjacent to the electrode layer is partially reduced.

29. The piezoelectric actuator as defined by claim 27, wherein the connection regions with partially reduced adhesive strength are distributed at least substantially uniformly over the actuator body.

30. The piezoelectric actuator as defined by claim 28, wherein the connection regions with partially reduced adhesive strength are distributed at least substantially uniformly over the actuator body.

31. A fuel injection valve, in particular an injector for fuel injection systems of air-compressing, self-igniting internal combustion engines, having a piezoelectric actuator as defined by claim 12, and a valve closing body, which is actuatable by the piezoelectric actuator and which cooperates with a valve seat face to make a sealing seat.
